(19) United States
(12) Patent Application Publication
(10) Pub. No.: US 2025/0159847 A1
(43) Pub. Date: May 15, 2025

(54) WATER-COOLED SYSTEM FOR DATA CENTER ROOM

(71) Applicant: Hebei Qinhuai Data Co., Limited., Zhangjiakou City (CN)

(72) Inventor: Binghua ZHANG, Zhangjiakou City (CN)

(21) Appl. No.: 18/944,128

(22) Filed: Nov. 12, 2024

(30) Foreign Application Priority Data
Nov. 15, 2023 (CN) 202311526510.8

(51) Int. Cl. H05K 7/20

(52) U.S. Cl. CPC H05K 7/20827; H05K 7/20318; H05K 7/20327

(57) ABSTRACT

The present disclosure discloses a water-cooling system for a data center room including a data center room, and a host positioned inside the data center room. A cooling plate is installed on a lateral side of the host, a cooling chamber is provided inside the cooling plate, a refrigerating plate is arranged inside the cooling chamber, an injector head is installed on an inner wall of the cooling chamber, and an absorption pipe is arranged at a bottom of the cooling chamber. A lateral side of the cooling plate is communicated with a gas-liquid separator, where a liquid outlet of the gas-liquid separator is connected to a liquid transmission pipe. In the water-cooling system for the data center room, the host having higher heat production is water cooled by means of the cooling plate, to meet demands for cooling down the host having higher heat production.

### CROSSREFERENCE TO RELATED APPLICATION

This application claims priority to Chinese Patent Application No. 202311526510.8, titled “WATER-COOLED SYSTEM FOR DATA CENTER ROOM” and filed to the China National Intellectual Property Administration on Nov. 15, 2023, the entire contents of which are incorporated herein by reference.

### TECHNICAL FIELD

The present disclosure relates to the field of water-cooling technology for a data center room, and more particularly, to a water-cooling system for the data center room.

### BACKGROUND

With the development of online business on the Internet, number of data center rooms progressively increases and construction scale thereof continuously extends, which causes increasing energy consumption of the data center rooms. This is because there are numerous electric devices and electrical devices in the data center rooms, and a lot of heat may be generated during operation of these devices.

However, most of the data center rooms are cooled down by means of central refrigeration devices. To meet demands for cooling down servers having higher heat production, temperature of the entire data center rooms needs to be lowered to a lower level. However, not all the servers or electrical devices are at a higher temperature during operation, so using this method may easily lead to waste of resources.

Generally, water cooling is used as a refrigeration means for indoor cooling of the data center rooms. Water-cooling systems for large data centers may generally have a water storage capacity of hundreds of tons of water. However, the data center rooms have lower water energy utilization rate, and it is difficult to collect heat generated in the data center rooms for reutilization. Therefore, there is provided a water-cooling system for a data center room.

### SUMMARY

In response to shortcomings of existing technologies, the present disclosure provides a water-cooling system for a data center room, which solves the problem raised in the background technology mentioned above.

To achieve the above objectives, the present disclosure is implemented through the following technical solutions. The water-cooling system for the data center room includes the data center room and a host positioned inside the data center room, where a cooling plate is installed on a lateral side of the host. A cooling chamber is provided inside the cooling plate, a refrigerating plate is arranged inside the cooling chamber, an injector head is installed on an inner wall of the cooling chamber, and an absorption pipe is arranged at a bottom of the cooling chamber. A lateral side of the cooling plate is communicated with a gas-liquid separator, where a liquid outlet of the gas-liquid separator is connected to a liquid transmission pipe, and a gas outlet of the gas-liquid separator is connected to a gas transmission pipe. An end of the liquid transmission pipe away from the gas-liquid separator is connected to a heat exchange box, and the heat exchange box is internally provided with a heat exchange tube, where an end of the heat exchange tube is connected to a first generator. The heat exchange box is communicated with a water-cooling tower through a fixedly connected water outlet pipe, and the water-cooling tower is configured to store and cool cooling water.

Alternatively, a water outlet end of the water-cooling tower is connected to a water-cooling device, where a water outlet end of the water-cooling device is connected to a delivery pump, a water outlet end of the delivery pump is connected to a water inlet pipe, and a tail end of the water inlet pipe is connected to the cooling plate.

Alternatively, a plurality of cooling chambers are arranged in an array inside the cooling plate, the injector head inside each of the plurality of cooling chambers is communicated with the water inlet pipe, and the absorption pipe inside each of the plurality of cooling chambers is communicated with the gas-liquid separator.

Alternatively, the heat exchange tube is spirally distributed inside the heat exchange box, and the heat exchange tube is internally filled with dichloromethane.

Alternatively, a second generator is connected to an end of the gas transmission pipe away from the gas-liquid separator, where an outlet end of the second generator is connected to a condenser, and the condenser is communicated with the water outlet pipe through a pipe.

Alternatively, a refrigerating mechanism is installed inside the data center room, and a cooling pipe is installed inside the refrigerating mechanism, where a water inlet end of the cooling pipe is communicated with the water inlet pipe through a fixedly connected distributive pipe I, a water outlet end of the cooling pipe is communicated with the liquid transmission pipe through a fixedly connected distributive pipe II, and an outside of the cooling pipe is fixedly provided with a refrigeration sheet.

Alternatively, a ventilation hole is provided on an upper side and a lower side of the refrigerating mechanism, and the refrigerating mechanism is internally provided with a ventilation fan positioned below the cooling pipe.

Alternatively, an outlet end of the first generator is connected to a steam cooling tower, where a bottom of the steam cooling tower is communicated with the heat exchange tube through a fixedly connected reflux pipe.

The present disclosure provides a water-cooling system for the data center room, which has the following beneficial effects.

1. In the water-cooling system for the data center room, the host having higher heat production is water cooled by means of the cooling plate, to meet demands for cooling down the host having higher heat production. The refrigerating mechanism is used to appropriately cool down the data center room, to meet demands for cooling down servers and electrical devices having lower heat production, thereby avoiding a problem of resource waste caused by traditional cooling of the entire data center room.

2. In the water-cooling system for the data center room, a plurality of separate cooling chambers are arranged inside the cooling plate, and the plurality of cooling chambers do not interfere with each other, thereby avoiding a problem that in traditional water cooling, the cooling water near the water inlet end has a lower temperature and thus has better cooling effects, but the cooling water near the water outlet end has a higher temperature and thus has poorer cooling effects. Furthermore, the injector head is used to eject the cooling water, in the form of water mist, onto the refrigerating plate, which can accelerate evaporation of water and absorb heat by means of the evaporation. Thus, this method has better heat dissipation effects than a heat conduction method where heat is transferred to the cooling water for heat dissipation.

3. In the water-cooling system for the data center room, hot water is separated from water vapor by means of the gas-liquid separator. A portion of the hot water enters the heat exchange box to heat the dichloromethane in the heat exchange tube, causing the dichloromethane to evaporate into gas. In the process of evaporation of the dichloromethane into the gas, the heat of the hot water may be absorbed, which can achieve preliminary cooling of the hot water. Meanwhile, the dichloromethane vapor can drive a worm gear of the first generator to rotate to generate power, which is conducive to energy recovery. A portion of the water vapor enters the second generator to drive the worm gear to rotate to generate power, which can achieve energy recycle.

### BRIEF DESCRIPTION OF THE DRAWINGS

FIG. 1 is a schematic structural diagram of the present disclosure;

FIG. 2 is a schematic structural diagram of the present disclosure from another angle;

FIG. 3 is a schematic diagram of an internal structure of a data center room of the present disclosure;

FIG. 4 is a schematic structural top view of the present disclosure;

FIG. 5 is a schematic structural sectional view of a cooling plate of the present disclosure;

FIG. 6 is a schematic structural diagram of a cooling chamber of the present disclosure;

FIG. 7 is a schematic structural diagram of a refrigerating mechanism of the present disclosure; and

FIG. 8 is a schematic structural diagram of a heat exchange tube of the present disclosure.

Reference numerals in the accompanying drawings: data center room 1; host 2; water-cooling device 3; delivery pump 4; water inlet pipe 5; cooling plate 6; cooling chamber 7; refrigerating plate 8; injector head 9; absorption pipe 10; distributive pipe I 11; refrigerating mechanism 12; ventilation hole 13; cooling pipe 14; refrigeration sheet 15; ventilation fan 16; distributive pipe II 17; gas-liquid separator 18; liquid transmission pipe 19; gas transmission pipe 20; heat exchange box 21; heat exchange tube 22; first generator 23; steam cooling tower 24; reflux pipe 25; second generator 26; condenser 27; water outlet pipe 28; and water-cooling tower 29.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure.

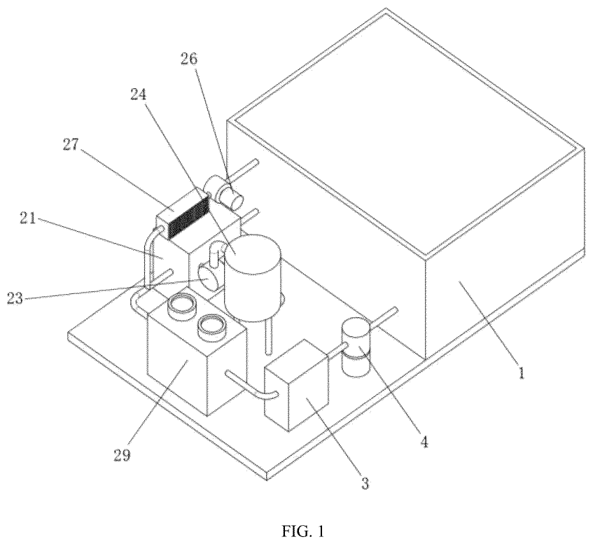

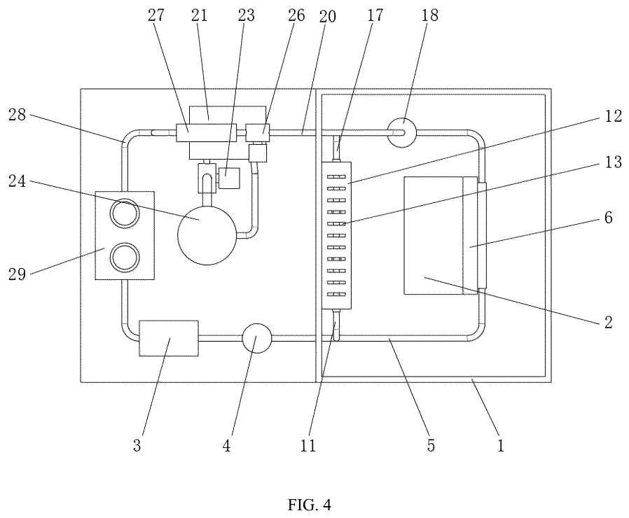

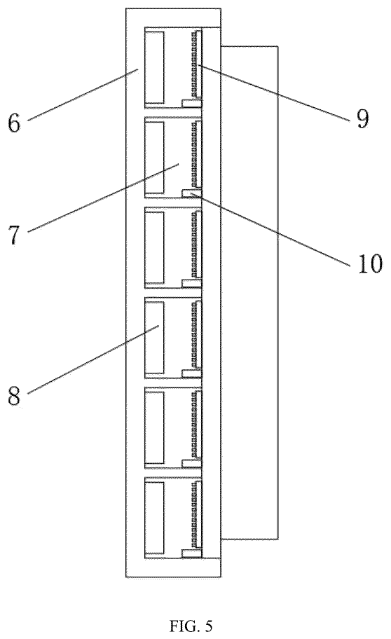

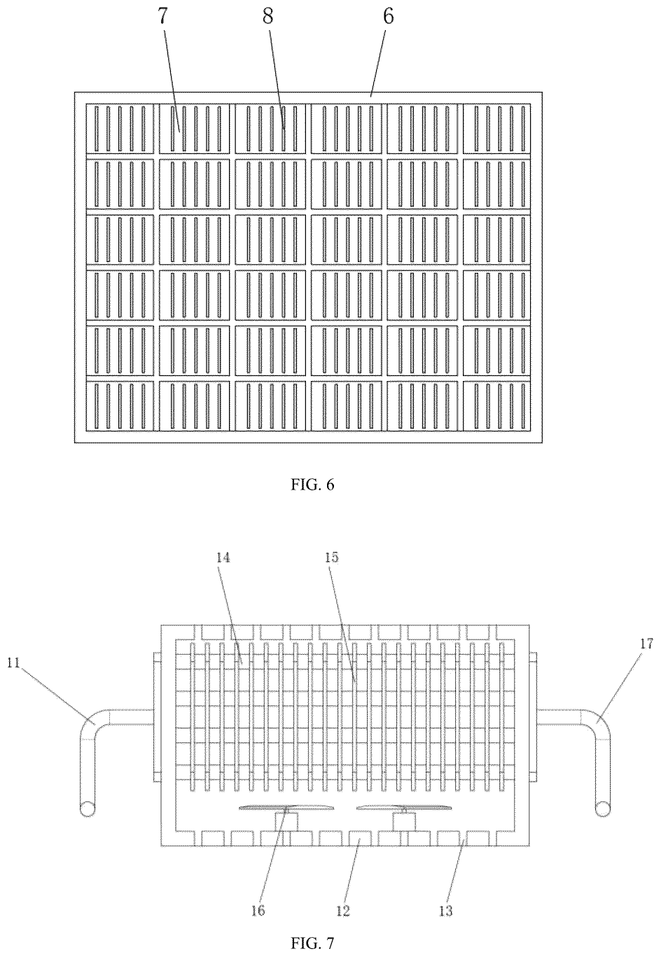

Referring to FIGS. 1 to 6, the present disclosure provides a technical solution as below. A water-cooling system for a data center room includes a data center room 1, a host 2 positioned inside the data center room 1, and a water-cooling tower 29 configured to store and cool cooling water. A water outlet end of the water-cooling tower 29 is connected to a water-cooling device 3, which is used to cool the cooling water and reduce its temperature. A water outlet end of the water-cooling device 3 is connected to a delivery pump 4, where a water outlet end of the delivery pump 4 is connected to a water inlet pipe 5, and a tail end of the water inlet pipe 5 is connected to a cooling plate 6, which is installed on a lateral side of the host 2, and a cooling chamber 7 is provided inside the cooling plate 6. A plurality of separate cooling chambers 7 are arranged inside the cooling plate 6, and the plurality of cooling chambers 7 do not interfere with each other, thereby avoiding a problem that in traditional water cooling, the cooling water near the water inlet end has a lower temperature and thus has better cooling effects, but the cooling water near the water outlet end has a higher temperature and thus has poorer cooling effects. A refrigerating plate 8 is arranged inside the cooling chamber 7, and the refrigerating plate 8 increases a contact area inside the cooling chamber 7, which is conducive to heat dissipation. An injector head 9 is installed on an inner wall of the cooling chamber 7, and an absorption pipe 10 is arranged at a bottom of the cooling chamber 7. Furthermore, the injector head 9 is used to eject the cooling water, in the form of water mist, onto the refrigerating plate 8, which can accelerate evaporation of water. Heat absorption by means of the evaporation has better heat dissipation effects than a heat conduction method where heat is transferred to the cooling water for heat dissipation. A plurality of cooling chambers 7 are arranged in an array inside the cooling plate 6, where the injector head 9 inside each of the plurality of cooling chambers 7 is communicated with the water inlet pipe 5, and the absorption pipe 10 inside each of the plurality of cooling chambers 7 is communicated with a gas-liquid separator 18.

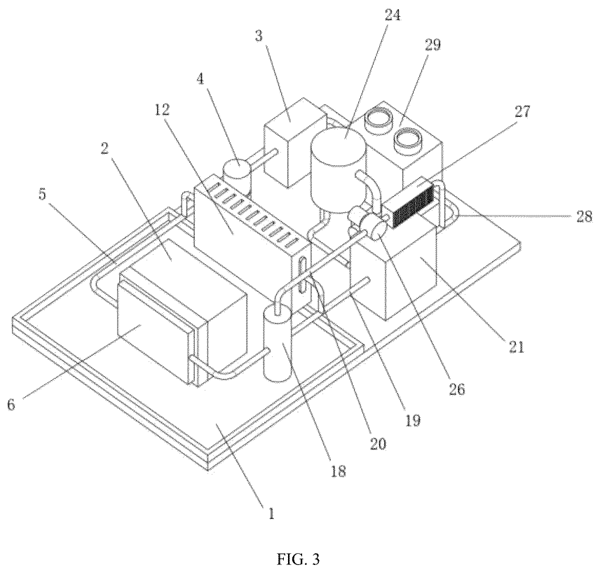

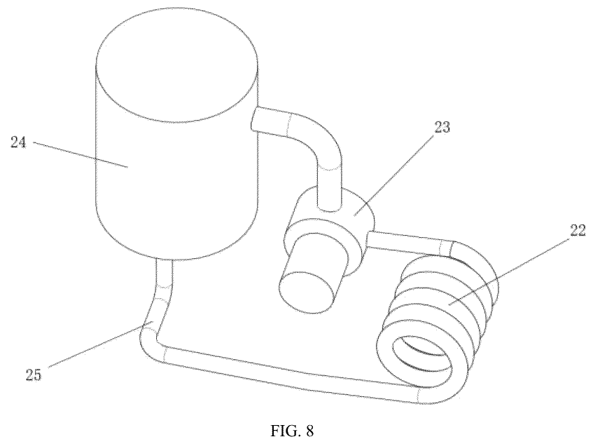

Referring to FIGS. 3 to 7, a refrigerating mechanism 12 is installed inside the data center room 1, and the refrigerating mechanism 12 is used to appropriately cool down the data center room, to meet demands for cooling down servers and electrical devices having lower heat production. A ventilation hole 13 is provided on an upper side and a lower side of the refrigerating mechanism 12, and the refrigerating mechanism 12 is internally provided with a ventilation fan 16 positioned below the cooling pipe 14. The ventilation fan 16 is arranged, such that the ventilation fan 16 is used to blow air upwards to accelerate circulation of the air inside the data center room 1. A cooling pipe 14 is installed inside the refrigerating mechanism 12, where a water inlet end of the cooling pipe 14 is communicated with the water inlet pipe 5 through a fixedly connected distributive pipe I 11, and a water outlet end of the cooling pipe 14 is communicated with the liquid transmission pipe 19 through a fixedly connected distributive pipe II 17. An outside of the cooling pipe 14 is fixedly provided with a refrigeration sheet 15. Arrangement of the refrigeration sheet 15 can accelerate heat transfer, which is beneficial for cooling down the inside of the data center room 1.

Referring to FIG. 3 and FIG. 8, a lateral side of the cooling plate 6 is communicated with the gas-liquid separator 18, where a liquid outlet of the gas-liquid separator 18 is connected to the liquid transmission pipe 19, and a gas outlet of the gas-liquid separator 18 is connected to a gas transmission pipe 20. An end of the liquid transmission pipe 19 away from the gas-liquid separator 18 is connected to a heat exchange box 21, and the heat exchange box 21 is internally provided with a heat exchange tube 22. By arranging the heat exchange tube 22, an area of contact between hot water and the heat exchange tube 22 is increased, which is conducive to evaporation of dichloromethane. The heat exchange tube 22 is spirally distributed inside the heat exchange box 21, and the heat exchange tube 22 is internally filled with the dichloromethane. An end of the heat exchange tube 22 is connected to a first generator 23. By arranging the first generator 23, dichloromethane vapor can drive a worm gear of the first generator 23 to rotate to generate power, which is conducive to energy recovery. An outlet end of the first generator 23 is connected to a steam cooling tower 24, and a bottom of the steam cooling tower 24 is communicated with the heat exchange tube 22 through a fixedly connected reflux pipe 25.

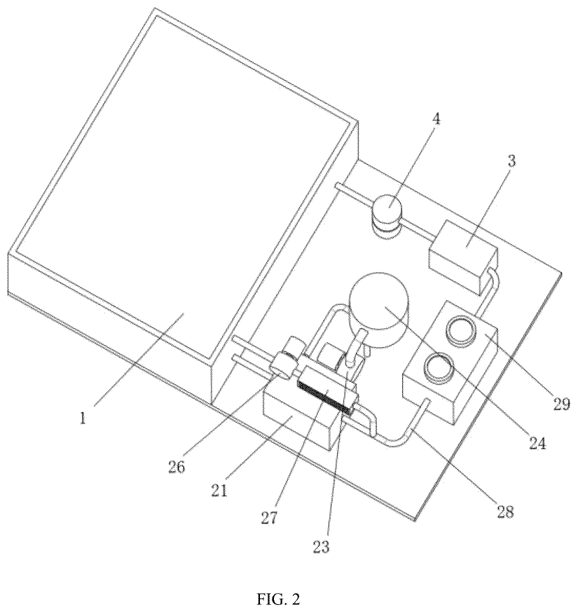

Referring to FIG. 2 and FIG. 3, an end of the gas transmission pipe 20 away from the gas-liquid separator 18 is connected to a second generator 26, where an outlet end of the second generator 26 is connected to a condenser 27. By arranging the second generator 26, a portion of water vapor enters the second generator 26 and drives the worm gear to rotate to generate power, which can achieve energy recycle. The heat exchange box 21 is communicated with the water-cooling tower 29 through a fixedly connected water outlet pipe 28, and the condenser 27 is communicated with the water outlet pipe 28 through a pipe.

In summary, when the water-cooling system for the data center room is in use, the water-cooling tower 29 transports the cooling water to the water-cooling device 3 for refrigeration, and then the delivery pump 4 transports the cooling water to the data center room 1. A portion of the cooling water is transported to the cooling plate 6, and then the injector head 9 ejects the cooling water, in the form of water mist, into the cooling chamber 7 for evaporative cooling, to cool down the host 2. The water vapor in the cooling chamber 7 is absorbed by the absorption pipe 10 and is transported to the gas-liquid separator 18 to separate the hot water from the water vapor. The hot water flows out of the liquid transmission pipe 19, and the water vapor flows out of the gas transmission pipe 20. Meanwhile, another portion of the cooling water is transported to the cooling pipe 14 through the distributive pipe I 11, such that the refrigeration sheet 15 cools down the air. The air inside the data center room is blown by the ventilation fan 16 to circulate, thereby cooling down the inside of the data center room. The cooling water after heat exchange flows into the liquid transmission pipe 19 through the distributive pipe II 17, and the hot water is transported to the heat exchange box 21 by means of the liquid transmission pipe 19. The dichloromethane in the heat exchange tube 22 is heated by the hot water, such that the dichloromethane evaporates into gas. In the process of evaporation of the dichloromethane into the gas, the heat of the hot water may be absorbed, which can achieve preliminary cooling of the hot water. Meanwhile, the dichloromethane vapor can drive the worm gear of the first generator 23 to rotate to generate power, then the dichloromethane vapor enters the steam cooling tower 24 and is cooled into liquid, and then the liquefied dichloromethane flows back into the heat exchange tube 22 through the reflux pipe 25 for recycling. The water vapor in the gas transmission pipe 20 is transported to the second generator 26 to drive the worm gear to rotate to generate power, then the water vapor enters the condenser 27 and is cooled into liquid, which flows into the water outlet pipe 28 and flows to the water-cooling tower 29 for cooling.

In the description of the present disclosure, it is to be noted that the orientation or position relations represented by the terms “center”, “above”, “beneath”, “left”, “right”, “vertical”, “horizontal”, “inside”, “outside” and the like are orientation or position relations shown based on the accompanying figures, they are merely for ease of a description of the present disclosure and a simplified description instead of being intended to indicate or imply the apparatus or element to have a special orientation or to be configured and operated in a special orientation. Thus, they cannot be understood as limiting of the present disclosure. Terms such as “first”, “second” and “third” are used only for purposes of description and are not intended to indicate or imply relative importance. In addition, it is to be noted that unless explicitly specified or limited otherwise, terms “installation”, “connecting” or “connection” should be understood in a broad sense, which may be, for example, a fixed connection, a detachable connection or integrated connection, a mechanical connection or an electrical connection, a direct connection or indirect connection by means of an intermediary, or an internal communication between two components. For those of ordinary skill in the art, specific meanings of the above terms in the present disclosure may be understood according to specific circumstances. Furthermore, terms such as “comprise”, “include” or other variants thereof are intended to cover a non-exclusive “include” such that a process, a method, a merchandise or a device comprising a series of elements not only includes these elements, but also includes other elements not listed explicitly, or also includes inherent elements of the process, the method, the merchandise or the device.

The abovementioned embodiments are merely preferred specific embodiments of the present disclosure, but the protection scope of the present disclosure is not limited thereto. Any equivalent substitution or variation easily conceivable to a person of ordinary skills in the art within the technical scope disclosed in the present disclosure based on the technical solutions of the present disclosure and inventive concepts thereof shall fall into the protection scope of the present disclosure.

What is claimed is:

1. A water-cooling system for a data center room, comprising a data center room (1) and a host (2) positioned inside the data center room (1), wherein a cooling plate (6) is installed on a lateral side of the host (2), a cooling chamber (7) is provided inside the cooling plate (6), a refrigerating plate (8) is arranged inside the cooling chamber (7), an injector head (9) is installed on an inner wall of the cooling chamber (7), and an absorption pipe (10) is arranged at a bottom of the cooling chamber (7); and
a lateral side of the cooling plate (6) is communicated with a gas-liquid separator (18), a liquid outlet of the gas-liquid separator (18) is connected to a liquid transmission pipe (19), a gas outlet of the gas-liquid separator (18) is connected to a gas transmission pipe (20), an end of the liquid transmission pipe (19) away from the gas-liquid separator (18) is connected to a heat exchange box (21), the heat exchange box (21) is internally provided with a heat exchange tube (22), an end of the heat exchange tube (22) is connected to a first generator (23), the heat exchange box (21) is communicated with a water-cooling tower (29) through a fixedly connected water outlet pipe (28), and the water-cooling tower (29) is configured to store and cool cooling water.

2. The water-cooling system for the data center room according to claim 1, wherein a water outlet end of the water-cooling tower (29) is connected to a water-cooling device (3), a water outlet end of the water-cooling device (3) is connected to a delivery pump (4), a water outlet end of the delivery pump (4) is connected to a water inlet pipe (5), and a tail end of the water inlet pipe (5) is connected to the cooling plate (6).

3. The water-cooling system for the data center room according to claim 1, wherein a plurality of cooling chambers (7) are arranged in an array inside the cooling plate (6), and the injector head (9) inside each of the plurality of cooling chambers (7) is communicated with the water inlet pipe (5), and the absorption pipe (10) inside each of the plurality of cooling chambers (7) is communicated with the gas-liquid separator (18).

4. The water-cooling system for the data center room according to claim 1, wherein the heat exchange tube (22) is spirally distributed inside the heat exchange box (21), and the heat exchange tube (22) is internally filled with dichloromethane.

5. The water-cooling system for the data center room according to claim 1, wherein a second generator (26) is connected to an end of the gas transmission pipe (20) away from the gas-liquid separator (18), an outlet end of the second generator (26) is connected to a condenser (27), and the condenser (27) is communicated with the water outlet pipe (28) through a pipe.

6. The water-cooling system for the data center room according to claim 1, wherein a refrigerating mechanism (12) is installed inside the data center room (1), a cooling pipe (14) is installed inside the refrigerating mechanism (12), a water inlet end of the cooling pipe (14) is communicated with the water inlet pipe (5) through a fixedly connected distributive pipe I (11), a water outlet end of the cooling pipe (14) is communicated with the liquid transmission pipe (19) through a fixedly connected distributive pipe II (17), and an outside of the cooling pipe (14) is fixedly provided with a refrigeration sheet (15).

7. The water-cooling system for the data center room according to claim 6, wherein a ventilation hole (13) is provided on an upper side and a lower side of the refrigerating mechanism (12), and the refrigerating mechanism (12) is internally provided with a ventilation fan (16) positioned below the cooling pipe (14).

8. The water-cooling system for the data center room according to claim 1, wherein an outlet end of the first generator (23) is connected to a steam cooling tower (24), and a bottom of the steam cooling tower (24) is communicated with the heat exchange tube (22) through a fixedly connected reflux pipe (25).
